(19) United States
(12) Patent Application Publication
(10) Pub. No.: US 2009/0201038 A1
(43) Pub. Date: Aug. 13, 2009

(54) TEST HEAD FOR FUNCTIONAL WAFER LEVEL TESTING, SYSTEM AND METHOD THEREFOR

(76) Inventor: JOHN U. KNICKERBOCKER, Monroe, NY (US)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 12/029,086

(22) Filed: Feb. 11, 2008

(51) Int. Cl. G01R 31/26; G01R 1/06

(52) U.S. Cl. 324/754

(57) ABSTRACT

A test head, system and method allowing functional wafer level testing of a test wafer, a die under test or a wafer under test, including at least one chip. The test head includes a semiconductor wafer and a series of protrusions in the semiconductor wafer. Each protrusion of the series of protrusions includes an electrical interconnection on a bottom surface of the semiconductor wafer, and a corresponding probe tip protruding from a top surface of the semiconductor wafer for establishing an electrical connection with a solder bump of the test wafer. The series of protrusion probe tips includes a pitch range of about 1 μm to about 100 μm.

### BACKGROUND OF THE INVENTION

1. Field of the Invention

The present invention generally relates to a test head for allowing functional wafer level testing of a wafer, a die under test or a wafer under test including at least one die including a chip before it is diced and joined with intermediate or final packaging. The test head has a series of silicon protrusions from a top surface of a semiconductor wafer for establishing electrical connection with solder bumps, pads or features of the wafer to be tested. The protrusions may be fabricated using semiconductor fabrication technology such that a protrusion pitch may be between about 1 μm to about 100 μm.

2. Description of the Related Art

Currently, semiconductor chips (especially high input/output (I/O) die and high function die) are functionally tested after they have been separated from a wafer via wafer dicing and joined with their final packaging.

When a semiconductor chip is determined to be less than fully functional or not functional whatsoever, the cost lost for a failed chip not only includes the semiconductor chip itself, but additionally includes all intermediate fabrication processes and the final packaging.

However, a conventional system and method require that a semiconductor chip be arranged in its final packaging to perform semiconductor chip testing with electrical chip leads of its final packaging.

A problem in attenuating the cost lost for intermediate fabrication processes and final packaging is attributable to an inability to provide a test apparatus having sufficiently high density I/O electrical contacts to perform functional testing at a wafer level. At present, an upper limit for most commercially available test probes is limited to about 512 total I/O per wafer contact or touchdown. An additional problem, for single chip products and for systems requiring multiple known good die to be integrated into a multi-chip product, is that each chip must be functionally tested independently from each other, thus increasing the cost and total product fabrication time for single chip products and followed by system testing of the integrated multi-chip module or product in the later case.

Thus, there exists a need to perform functional wafer level testing on a wafer including multiple chips at the same time or to test die assembled in die stacks on a wafer, to understand which die or die stacks are functionally good, partially good, to perform speed sorts or other test characterization and thus before the wafer is diced and semiconductor chips are further processed for integration with their appropriate value add and final packaging.

### SUMMARY OF THE INVENTION

In view of the foregoing and other exemplary problems, drawbacks, and disadvantages of the conventional methods and structures, an exemplary feature of the present invention is to provide a test head for allowing functional wafer level testing of an un-diced test wafer, a die under test or a wafer under test that includes at least one chip, wherein the test head may include a wafer, at least two protrusions in the wafer, each of the protrusions including, an electrical interconnection on a first surface of the wafer, and a probe tip protruding from a second surface of the wafer for establishing an electrical connection with a solder bump, pad or feature of the die under test (DUT) or wafer under test (WUT).

In another exemplary aspect of the present invention, a system for providing functional wafer level testing of an un-diced test wafer including at least one chip may include a test head including a wafer, at least two protrusions in the wafer, each protrusion of the at least two protrusions including an electrical interconnection on a first surface of the wafer, and a probe tip protruding from a second surface of the wafer for establishing an electrical connection with a solder bump of the DUT or WUT, a substrate supporting the test head and electrically connecting to the test head through the electrical interconnections, and a tester electrically connected to the test head through the substrate functionally testing at least one circuit on the test wafer when the electrical connection is established by the protruding probe tips.

Another exemplary aspect of the present invention may include the protruding probe tips comprising a pitch range of about 1 μm to about 100 μm.

Another exemplary aspect of the present invention wherein the wafer may include an integrated functional tester including internal circuitry to perform test function locally, reducing the cost of the overall tester, to perform faster testing or to perform integrated smart probe with a portion of the active system integrated into the smart probe while testing one or more remaining die in the functional test or to step through segments of the die under test or wafer undertest using high I/O probes and electronic sequencing to characterize portions or all of the chip function as test requirements are specified.

Another exemplary aspect of the present invention may include at least one of the at least two protrusion probe tips includes a portion for puncturing through an oxide layer on the solder bump to establish a low resistance electrical connection through the solder bump with the test wafer or causing a mechanical scrub to a surface, pad or feature to be contacted on the die or wafer once again to obtain a low resistance electrical connection.

Another exemplary aspect of the present invention may include at least one of the at least two protrusion probe tips includes at least two parallel disposed bars to establish an electrical connection through the solder bump with the test wafer.

Another exemplary aspect of the present invention may include at least one of the at least two protrusion probe tips includes an annular protrusion probe tip to establish an electrical connection through the solder bump with the test wafer.

Another exemplary aspect of the present invention may include at least one of the at least two protrusion probe tips includes a double annular protrusion probe tip to establish an electrical connection through the solder bump with the test wafer, the double annular protrusion probe tip includes a first annular protrusion probe tip, a second annular protrusion probe tip disposed within the first annular protrusion probe tip, and a resilient biasing polymer disposed inside the first annular protrusion probe tip and between the wafer and the second annular protrusion probe tip, wherein the resilient biasing polymer biases the second annular protrusion probe tip in a direction away from the wafer.

Another exemplary aspect of the present invention may include at least two protrusion probe tips are formed on the second surface of the wafer by an etch back process.

Another exemplary aspect of the present invention may include at least two protrusion probe tips are metallized such as with copper-nickel-gold; copper-nickel-palladium-cobalt; tungsten-nickel gold; molybdenum-nickel-gold; tungsten-copper-nickel-palladium-cobalt or alloys there-in or alternate metal tip.

In still another aspect, the method according to the exemplary aspects of the present invention may include providing a test head including a wafer, at least two protrusions in the wafer, each protrusion of the at least two protrusions including an electrical interconnection on a first surface of the wafer, and a corresponding probe tip protruding from a second surface of the wafer for establishing an electrical connection with a solder bump of the test wafer, electrically joining the test head to the test wafer through the at least two protrusion probe tips, and functionally testing the test wafer.

Accordingly, another exemplary aspect of the present invention, the method according to the present invention may include at least one of one of heating and cooling the test head during the functional testing of the test wafer, cleaning at least one of the at least two protrusion probe tips, reworking at least one of the at least two protrusion probe tips, simultaneously reworking at least one of the at least two protrusion probe tips and the wafer, and reworking the electrical interconnection of the test head.

### BRIEF DESCRIPTION OF THE DRAWINGS

The foregoing and other exemplary purposes, aspects and advantages will be better understood from the following detailed description of an exemplary embodiment of the invention with reference to the drawings, in which:

FIG. 1A illustrates a first exemplary embodiment of the test head, according to an exemplary aspect of the present invention;

FIG. 1B illustrates the first exemplary embodiment of the test head, taken as a cross section A-A from FIG. 1A, according to an exemplary aspect of the present invention;

FIG. 2A illustrates a second exemplary embodiment of the test head, further illustrating a single point probe tip embodiment, according to an exemplary aspect of the present invention;

FIG. 2B illustrates the second exemplary embodiment of the test head, further illustrating an array of single point probe tips, according to an exemplary aspect of the present invention;

FIG. 3 illustrates a third exemplary embodiment of the test head, further illustrating a bar probe tip embodiment, according to an exemplary aspect of the present invention;

FIG. 4 illustrates a fourth exemplary embodiment of the test head, further illustrating an annular probe tip embodiment, according to an exemplary aspect of the present invention;

FIG. 5A illustrates a fifth exemplary embodiment of the test head, further illustrating a double annular probe tip embodiment, according to an exemplary aspect of the present invention;

FIG. 5B further illustrates the fifth exemplary embodiment of the test head, further illustrating a top view of the double annular probe tip embodiment, according to an exemplary aspect of the present invention;

FIG. 5C further illustrates the fifth exemplary embodiment of the test head, further illustrating a side cross-sectional view B-B from FIG. 5B, according to an exemplary aspect of the present invention;

FIG. 5D further illustrates the fifth exemplary embodiment of the test head, further illustrating a side cross-sectional view B-B from FIG. 5B when the resilient biasing polymer is in a compressed state, according to an exemplary aspect of the present invention;

FIG. 6 illustrates a general embodiment of the test head, further illustrating an electrical joining of a test wafer with the test head, according to an exemplary aspect of the present invention;

FIG. 7 illustrates a general embodiment of the test head, further illustrating the electrical joining of a test integrated chip stack with the test head, according to an exemplary aspect of the present invention;

FIG. 8 illustrates a general embodiment of the test head, further illustrating an integrated functional tester with the test head, according to an exemplary aspect of the present invention;

FIG. 9 illustrates a general embodiment of the test head, further illustrating the electrical joining of a test wafer with the functional tester and the test head, according to an exemplary aspect of the present invention;

FIG. 10 illustrates a general embodiment of a method for function wafer level testing according to an exemplary aspect of the present invention; and

FIG. 11 illustrates an alternative embodiment of the test head of FIG. 6, further illustrating an electrical joining of a test wafer with the test head, according to an exemplary aspect of the present invention.

### DETAILED DESCRIPTION OF EXEMPLARY EMBODIMENTS OF THE INVENTION

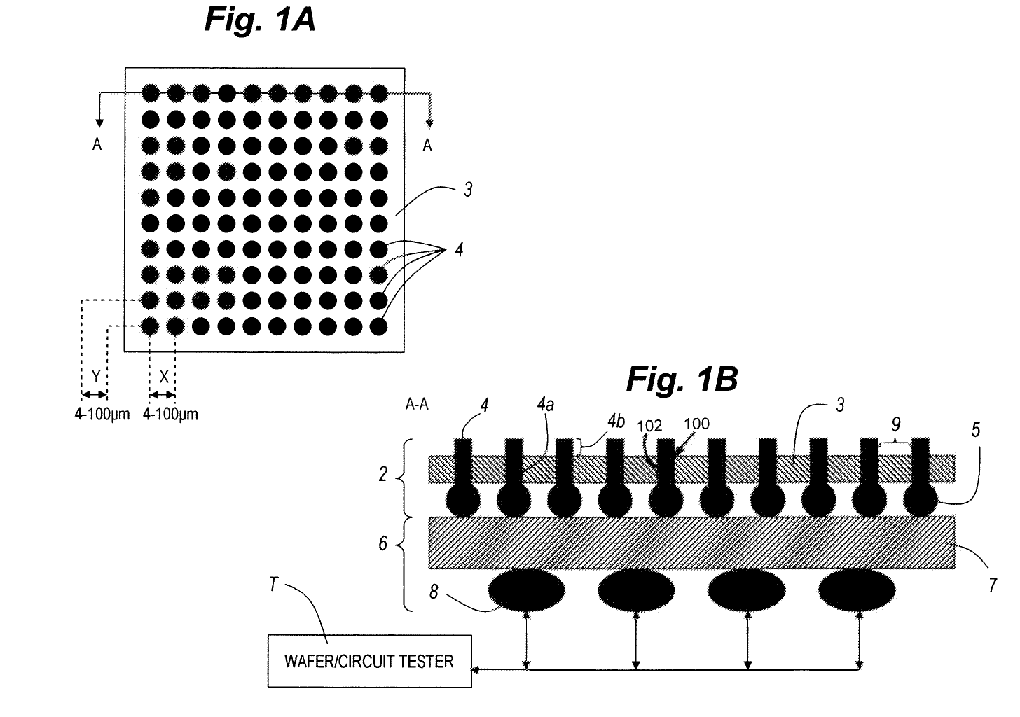

Referring now to the drawings, and more particularly to FIGS. 1A-10, there are shown exemplary embodiments of the method and structures of the present invention.

FIGS. 1A-1B illustrate a first exemplary embodiment of the invention that includes a test head 2 including of a wafer 3 and an array, (as shown in FIG. 1A), or series of protrusions 4 located in and projecting from the wafer 3. Wafer 3 may be silicon-based, for example, SiGe, or may be comprised of other common wafer materials, for example, GaAs.

The series of protrusions 4 each include an internal through via portion 4a disposed through the wafer 3, a projecting silicon protrusion probe tip 4b above the upper surface of the wafer 3, and a through via interconnection 5 with underfill bonding below the lower surface of the wafer 3 for connection to a wafer/circuit testing machine T and/or further circuitry. A substrate layer 6 includes a substrate 7 for supporting the test head 2 on an upper surface of the substrate 7, and electrical interconnections 8 on a lower surface of the substrate 7 to connect to a next level of circuitry and/or the wafer/circuit tester T. Wafer/circuit tester T provides an integrated functional tester including internal circuitry that provides functionality to increase speed for testing procedure, lower the cost of test equipment, provide high frequency testing, provide a multi-chip or multi-die stack functional testing, provide a multi-chip or multi-die stack speed sorting, provide partial good die sorting, provide high I/O test characterization, or provide alternate test characterization.

The series of silicon protrusions 4 are constructed in an exemplary configuration in an array, (see FIG. 1A), having a horizontal pitch X and/or a vertical pitch Y of a range between 4 to about 100 μm. Protrusions 4 may be configured in any shape, that is, any number of columns and rows necessary to test correspondingly configured wafers. Each projecting protrusion probe tip 4b is created via an etch back process in an etch back region 9 on the surface of the semiconductor wafer 3 between each of the series of protrusions 4 such that the protrusion probe tip 4b projects above the upper surface of the wafer 3.

Examples of the process of forming the probe tips may include but are not limited to using blanket metal copper deposition which may be several microns thick and may then be chemically etched to form the copper shaped probe tips. Subsequent plating or deposition of harder metallurgies other than copper such as Ni, Pt, etc., can be formed over the shaped copper to create a contact which is more resistant to mechanical abrasion and corrosion. Additionally, a plate up process with sequential lithographic definition, resist and plating may create a probe tip that is desired with subsequent depositions of surface metallurgy. Further, probe tips may be fabricated by the transfer of metal probes from a polymer sheet with surface metallurgy that has been formed to create probe tips by means of copper to copper bonding or alternate attachment techniques.

The series of protrusions 4 may be metallized to enhance their electrical conductivity to engage a test wafer having one or more chips through metallization of Cu, or a W core, Ni and a Pt, Au or Ru composition. Probe tips may be composed of other suitable metallurgies or alloys of metals. Alternative depositions may include hard metallurgies, for example, W or Mo, or other surface coatings with Pt, Rh, Ru, or other metallurgies or alloys

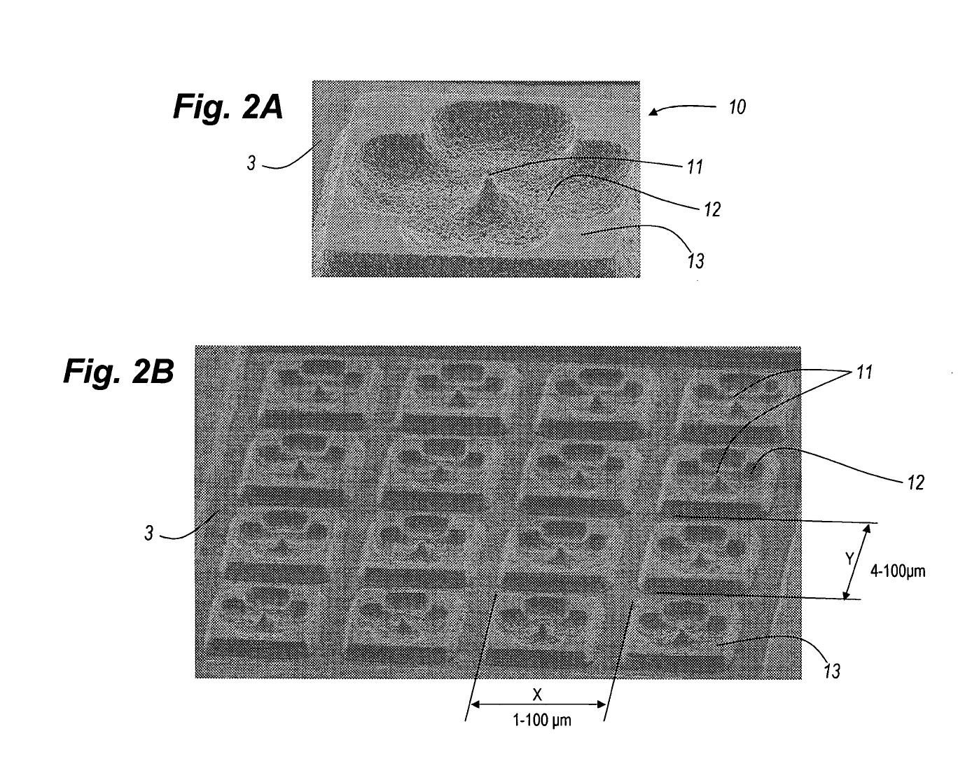

FIGS. 2A-2B illustrate a second exemplary alternative embodiment of the test head wherein the projecting protrusions probe tips 4b of FIGS. 1A-1B are configured in a single point (i.e., or a single contact portion) protrusion probe tip 10. A point 11 is surrounded by a surrounding recess 12 created by an etch-back process located on a projecting table portion 13 of the wafer 3. Each point 11 is configured to puncture through an oxide layer on a solder bump of a test wafer to establish an electrical connection. The surrounding recess 12 is designed to eliminate oxide fouling of the point 11 which prolongs the cleaning cycle and the touchdown or lifecycle of the series of protrusions 4 on the test head 2 when establishing electrical connectivity with test wafers.

For FIGS. 1 and 2A-2B, probe tip shapes can be formed using deep reactive ion etch to form vertical connections through silicon to an appropriate depth (each example can be <10 μm to about 150 μm in depth), followed by thermal oxidation to form an insulator or use of Plasma-enhanced chemical vapor deposition (PECVD) insulator deposition, and then chemical vapor deposition (CVD) of W or Mo into vertical holes and wafer thinning to open both sides of the structure. Alternate metallurgy can be plated copper in via holes. The wafer is then thinned from the back side to open up metal contacts by means of grinding, polishing, reactive ion etch, chemical etch or alternate thinning. Additionally, an insulator is deposited over the silicon to provide insulation for the conductors. Then probe structures can be fabricated as described above with etched copper metal pads which then form a probe tip which looks like a large center protrusion and surrounding clover leaf, (see FIGS. 2A-2B), followed by plating or metal deposition over the probe to add surface metallurgies to enhance wear resistance and for better electrical contact with a lower contact resistance.

FIG. 2B illustrates an array of projecting protrusions probe tips having a single point protrusion probe tip 10 configuration. Each of the single point protrusion probe tips 10 is configured in the array having a horizontal pitch X between 1 μm to about 100 μm and a vertical pitch Y between 1 μm to about 100 μm.

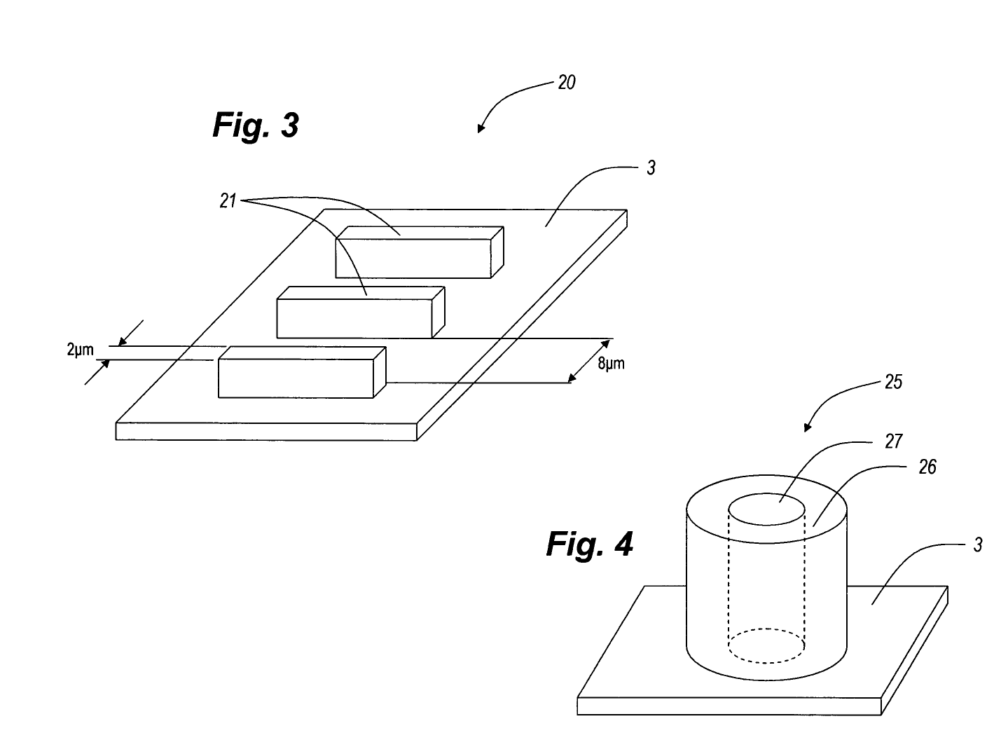

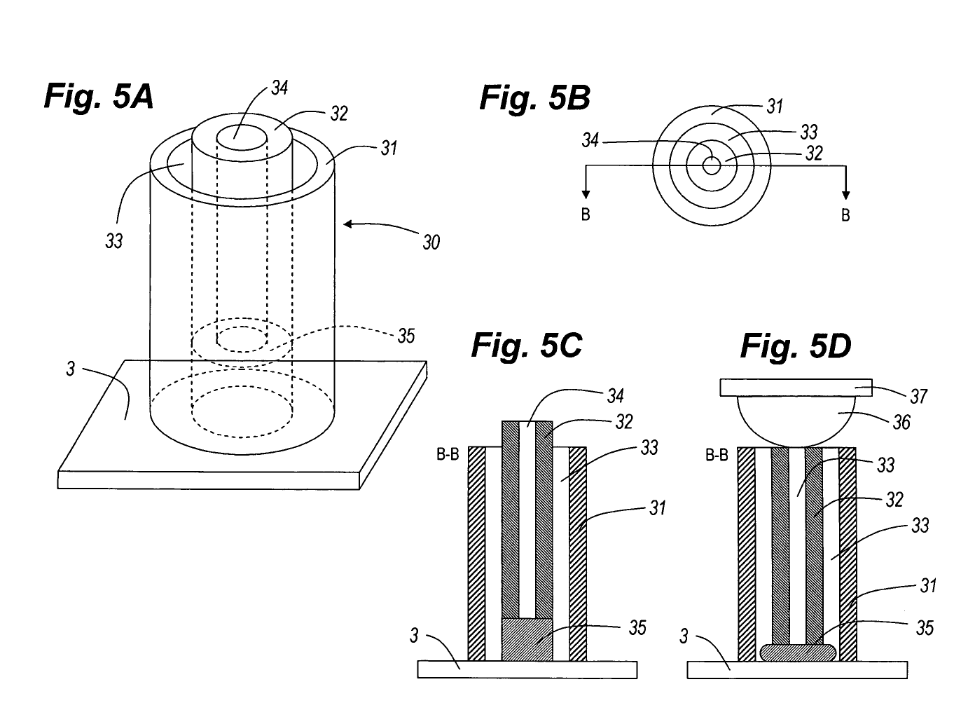

In FIGS. 3 to 5, the vertical shapes (bars in FIG. 3, and annular rings in FIGS. 4-5D) may be formed by deep reactive ion etch in silicon wafer or an equivalent wafer material of appropriate depth followed by insulator deposition or thermal oxide formation for an insulator, then followed by W or Mo CVD deposition to form the metal ring structure (FIGS. 4, 5A-D) or bars (FIG. 3). Alternate metallurgy can be plated copper in via holes. Then wafer is thinned from back side to open up metal contacts by means of grinding, polishing, reactive ion etch, chemical etch or alternate thinning. In addition, an insulator is deposited over the silicon to provide insulation for the conductors. Surface metallization depositions or plating of finishing metallurgies such as Cu—Ni—Au; Cu—Ni Pd—Co; Ni—Au, Ni—Pd—Co or alternate finish deposition metallurgy for purposes of improved electrical, mechanical and thermal robustness provides for enhance probe tip lifetime and performance under test.

FIG. 3 illustrates a third exemplary alternative embodiment of the test head wherein the projecting protrusion probe tips 4b of FIGS. 1A-1B are configured in a bar protrusion probe tip configuration 20. Here, each series of protrusions 4 has a projecting protrusion probe tip including at least two protrusion probe tip bars 21 arranged in a parallel disposition on the upper surface of the wafer 3. An exemplary configuration of this embodiment dimensions protrusion probe tip bar 21 to be about 2 μm in width and may be spaced at a distance of about 8 μm from each parallel disposed protrusion probe tip bar 21 in one example. Alternate structures may be scaled larger or smaller for alternate dimensional configurations to be used depending on the corresponding wafer contact geometry.

In FIG. 3, ends of the protruding bars can be extended by etching back Si and oxide to a depth of desired protrusion. In FIG. 4, the annular structure may then have its annular end extended by etching back Si and oxide for desired protrusion level. Other metallurgies may be deposited on the probe tips to enhance the probe tip use conditions such as abrasion resistance and low contact resistance surface metallurgy deposition using Cu—Ni—Au, Cu—Ni—Pd—Co, Ni—Au, Ni—Pd—Co or alternate probe tip finishing metallurgy.

FIG. 4 illustrates a fourth exemplary alternative embodiment of the test head wherein the projecting protrusion probe tips 4b of FIGS. 1A-1B are configured in an annular protrusion probe tip configuration 25. In this embodiment, an annular protrusion probe tip 26 projects from the upper surface of the wafer 3 and includes a centrally located air gap 27 disposed along the longitudinal axis of the annular protrusion probe tip 26.

FIGS. 5A-5D illustrate a fifth exemplary alternative embodiment of the test head wherein the projecting protrusion probe tips 4b of FIGS. 1A-1B are configured in a double annular protrusion probe tip configuration 30. In this embodiment, a first annular protrusion probe tip 31 projects from the upper surface of the wafer 3. A second annular resiliently biased protrusion probe tip 32 is centrally located within the first annular protrusion probe tip 31. A first air gap 33 is disposed between the first annular protrusion probe tip 31 and the second annular protrusion probe tip 32 in addition to a second air gap 34 centrally disposed along the longitudinal axis of the second annular protrusion probe tip 32.

A resilient biasing conductive polymer 35 in an uncompressed state, a shown in FIGS. 5A and 5C, is located on the inside of the first annular protrusion probe tip 31 and under the second annular protrusion probe tip 32 for biasing the second annular protrusion probe tip 32 in a direction away from the wafer 3. When a micro-bump solder connection 36 of a test wafer 37 comes into contact with a distal end of the second annular protrusion probe tip 32, the resilient biasing conductive polymer 35 compresses to a state, as shown in FIG. 5D, to thereby retract the second annular protrusion probe tip 32 into the first annular protrusion probe tip 31 towards the direction of the wafer 3. Upon removal of the micro-bump solder connection 36 and test wafer 37, the resilient biasing conductive polymer returns to its uncompressed state 35a and biases the second annular protrusion probe tip 32 in a direction away from the wafer 3. The advantage of this resiliently biased protrusion tip embodiment is to prolong the life of the test head by reducing contact stress related wear on the protrusion tip during testing operation.

In FIGS. 5A-5D, the end of the probe tips may later be raised by etching back the Si and or Si oxide on either the top or bottom of the structure. For the double ring or wire in an annular structure, one or the other shape may be released from the oxide or Si by an addition of another deep reactive ion etch or by use of a chemical etch for the appropriate designed structure with multiple annular structures and sacrifice of one or more of the annular structures to etching and or removal. Once released, the extension of wire or annular ring can be connected to a conductive polymer 35 or alternate conductive and compliant material. Therefore, the conductive polymer 35 can be deposited the inside annular structure 31 once a wire or inner annular wires 32 are extended.

Another benefit of the extended probe 32 of FIGS. 5A-5D is to support a non-coplanarity of bump heights to be tested as well as the ability to test bump or pad heights of different heights and or diameters. (Another alternative to achieve probes with more than one fixed probe heights above the die under test or wafer under test is to have predefined probes fabricated to more than one height if the wafer or die under test has multiple solder bump, pad or contact pad heights.

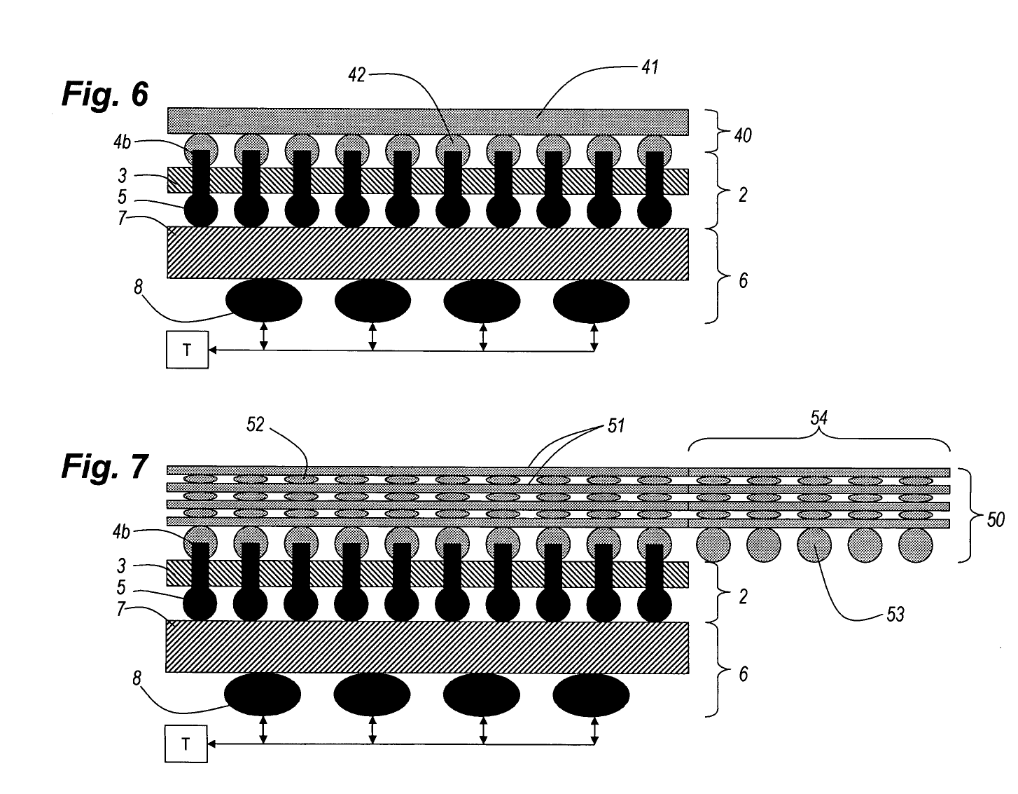

FIG. 6 illustrates a general embodiment of the test head 2 in combination with a test wafer 40 that includes a semiconductor wafer 3 with one or more chips 41 and a plurality of micro-bump solder connections 42 having a size of around 1-2 μm in diameter. Test wafer 40 may also include a die under test (DUT) or a wafer under test (WUT) with connections 42 including solder connections, pads or other electrical contact features. When the test head 2 and the attached accompanying substrate layer 6 are brought into contact with the test wafer 40, the projecting through protrusion tips 4b make connection by contacting a portion of the micro-bump solder connection 42 to electrically connect the test head 2 with the test wafer 40. Upon electrical connection, a wafer and/or circuit tester T (FIG. 1B), may perform functional testing of the test wafer 40 or individual circuit portions on the test wafer 40.

FIG. 7 illustrates a second alternative general embodiment of the test head 2 in combination with a test integrated chip stack 50 (or integrated stacked wafers), that includes semiconductor stacked wafer layers 51 with one or more stacked chips, stacked layer interconnections 52 and a plurality of micro-bump solder connections 53. When the test head 2 and the attached accompanying substrate layer 6 are brought into contact with the test integrated chip stack 50, the projecting protrusion probe tips 4b make connection by contacting a portion of the micro-bump solder connection 53 to electrically connect to test head 2 with the integrated chip stack 50. Upon electrical connection, wafer and/or circuit tester T (FIG. 1B), may perform functional testing on the integrated chip stack layer 50, or a specific portion of an adjacent co-joined test integrated chip stack 54.

The test integrated chip stack 50 may further comprise multi-layer active circuits, die stacks, a die stack on a wafer, or a modular integrated die.

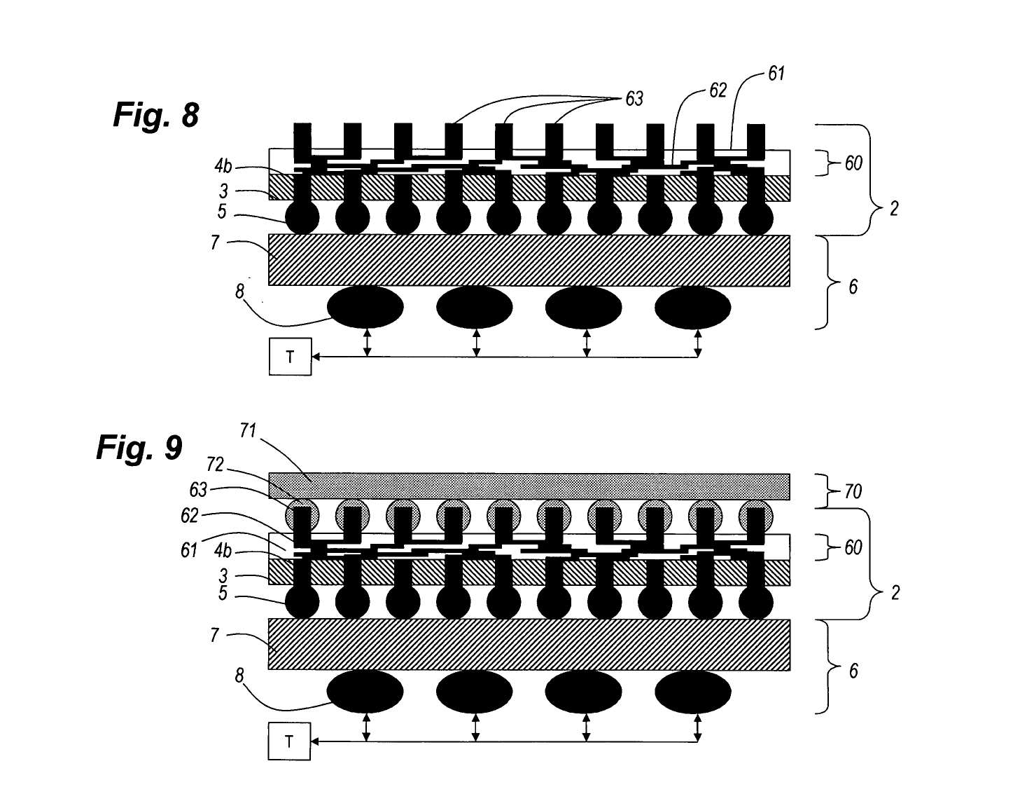

FIGS. 8-9 illustrate an alternative embodiment of the test head 2 as previously described in FIGS. 1B and 6. Incorporated into test head 2 is a semiconductor integrated functional tester 60 that includes a functional tester semiconductor wafer 61 having wiring and/or circuitry 62 therein. Protrusion test probes 63 project above the test head 2 which are connected to the semiconductor integrated functional tester 60 and ultimately through the test head 2 to the through via interconnections 5. The test head 2 incorporating the semiconductor integrated functional tester 60 engages a test wafer 70 having a semiconductor wafer 71 with one or more chips/chip stacks via the micro-bump solder connections 72 in the manner described above.

The semiconductor integrated functional tester 60 may include off-chip wiring, signal wiring to mimic off-circuit wiring, fan in and fan out, integrated coupling capacitors and/or electrostatic discharge diodes, active circuitry and passive circuitry.

The semiconductor integrated functional tester 60 may also include power distribution and voltage regulation circuitry. Multiple voltages and locally provided voltage reduce voltage noise, thereby allowing higher testing frequencies when used in conjunction with an integrated coupling capacitor in the integrated functional tester 60.

The semiconductor integrated functional tester 60 allows the test head 2 to be fabricated into standard configurations for adaptation with the semiconductor integrated functional tester 60 per the wafer level testing requirements.

Additionally, the probe head 2 may be separate from the integrated functional tester 60 and fabricated without protrusion probe tips 4b projecting above an upper surface, (as shown in FIG. 1), so that the standard hardware (i.e., functional tester 60) may be fabricated with the projecting protrusion probe tips 63, or with standard pitch silicon protrusions to shorten fabrication time of the test head 2.

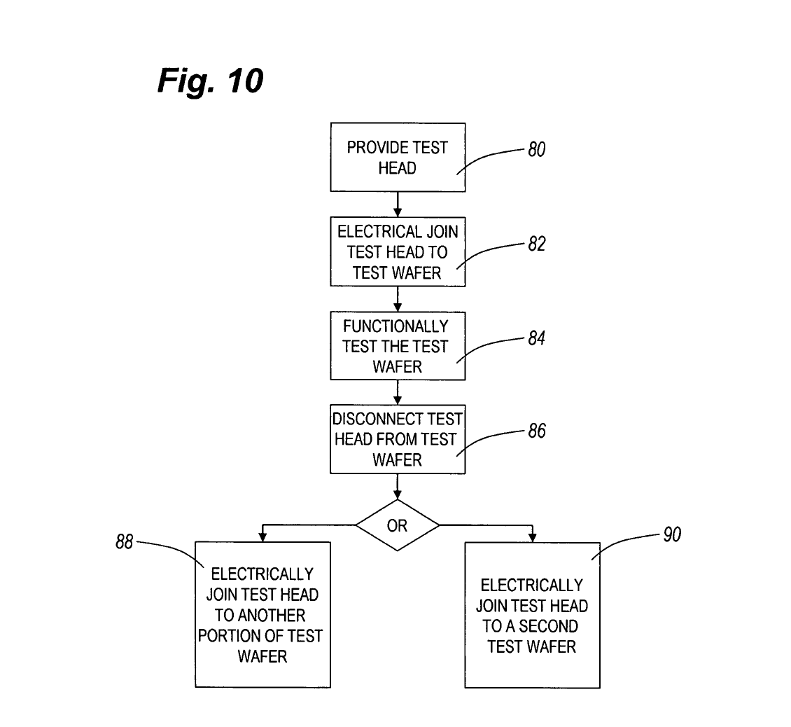

FIG. 10 illustrates a method for functional wafer level testing of a test wafer or a portion of a test wafer including at least one chip includes providing a test head 2 including a wafer 3 and a series of protrusions 4 wherein each of the series of protrusions 4 include a probe tip 4b protruding from a top surface of the wafer 3 for establishing an electrical connection with a solder bump of a test wafer. Reference number 80 illustrates providing the test head such that the projecting protrusion probe tips 4b electrically join 82 the test head 2 to the test wafer to allow the wafer/circuit tester T to functionally test the wafer and/or at least one circuit on the wafer. The projecting protrusion probe tips 4b then electrically disconnect 84 the test head 2 from the test wafer by disengaging the series of protrusion probe tips 4b from the solder bumps of the test wafer. The test head 2 is now able to be moved to a different portion of the test wafer for testing an additional circuit on the test wafer 88, or may be electrically joined to a second test wafer 90 through the series of protrusion probe tips 4b to test the second test wafer or an individual circuit or circuits on the second test wafer.

The test head 2 may be brought to an operating temperature of the test wafer by either heating or cooling the test head 2 in conjunction with the test wafer during the testing process allowing for the testing of the test wafer under normal operating conditions.

An additional advantage of the present configuration of the invention is that the projecting protrusion probe tips 4b may be cleaned and re-worked to prolong the life and reliability of the test head 2. Additionally, the protrusion probe tips 4b and the wafer 3 may be reworked simultaneously to prolong the life and reliability of the test head 2. Further, the electrical interconnection 8 of the test that 2 may be reworked to prolong the life a reliability of the test head 2. Each of these methods facilitates an increase in the duration of the cleaning cycle and the touchdown or lifecycle of the test head 2.

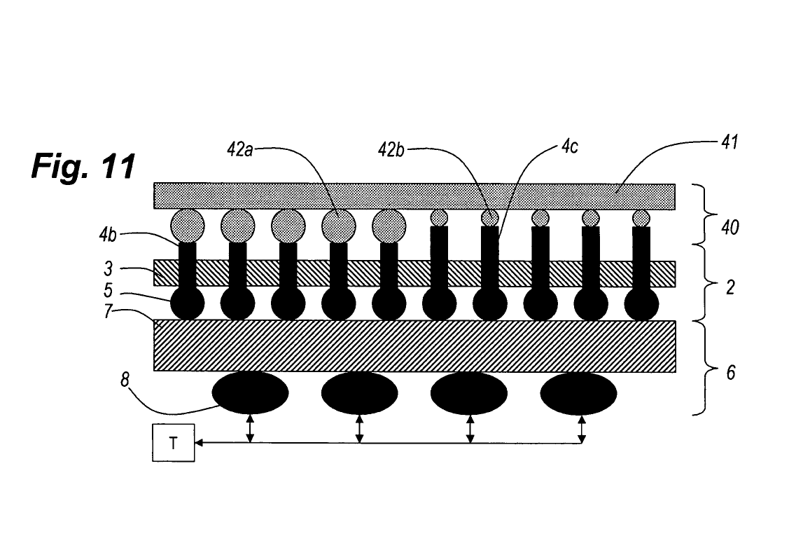

FIG. 11 illustrates an alternative embodiment similar to the one shown in FIG. 6, except in addition to the plurality of micro-bump solder connections 42a, a plurality of micro-bump solder connections 42b having a height relative to the test head 2 different than that of connections 42a. The embodiment of FIGS. 5A-5D allow for protrusion tips 4b to be extended to different heights above the test head 2 to accommodate micro-bump solder connections 42a and 42b having a plurality of heights. Thus, connections 42a and corresponding protrusions 4b have a first planar height from the test head 2, while connections 42b and corresponding protrusions 4c have a second and different planar height from the test head 2. In contrast, FIG. 6 shows connections 42 and corresponding protrusions 4b having a single planar height distance from the test head 2.

While the invention has been described in terms of one or more exemplary embodiments, those skilled in the art will recognize that the invention can be practiced with modification within the spirit and scope of the appended claims. Specifically, one of ordinary skill in the art will understand that the drawings herein are meant to be illustrative, and the design of the inventive assembly is not limited to that disclosed herein but may be modified within the spirit and scope of the present invention.

Further, Applicant's intent is to encompass the equivalents of all claim elements, and no amendment to any claim the present application should be construed as a disclaimer of any interest in or right to an equivalent of any element or feature of the amended claim.

1. A test head for a functional wafer level testing said test head comprising:
a wafer;
a plurality of finely-spaced protrusions in said wafer, each of the protrusions isolated by a layer of a dielectric material, each of said protrusions comprising:
an electrical interconnection on a first surface of said wafer; and
a probe tip protruding from a second surface of said wafer for establishing an electrical connection with a contact including a solder bump of one of a test wafer, a die under test, a wafer under test, and stacked test wafers, and the probe tip electrically communicating with the electrical interconnection for the functional wafer testing.

2. The test head according to claim 1, wherein said protrusion probe tips comprise a pitch range of approximately 1 μm to approximately 100 μm.

3. (canceled)

4. The test head according to claim 1, wherein at least one of said plurality of protrusion probe tips comprises:
a portion for puncturing through an oxide layer on said solder bump to establish a low resistance electrical connection through said solder bump with said test wafer, and a recess surrounding the portion for puncturing, for eliminating an oxide fouling of the portion for puncturing.

5. The test head according to claim 1, wherein at least one of said plurality of probe tips comprises:
at least two parallel disposed bars to establish an electrical connection through said solder bump with said test wafer.

6. The test head according to claim 1, wherein at least one of said plurality of protrusion probe tips comprises:
an annular protrusion probe tip to establish an electrical connection through said solder bump with said test wafer.

7. The test head for allowing functional wafer level testing according to claim 1, wherein at least one of said plurality of protrusion probe tips comprises:
a double annular protrusion probe tip to establish an electrical connection through said solder bump with said test wafer, said double annular protrusion probe tip comprising:
a first annular protrusion probe tip;
a second annular protrusion probe tip disposed within said first annular protrusion probe tip; and
a resilient biasing polymer disposed inside said first annular protrusion probe tip and between said wafer and said second annular protrusion probe tip,
wherein said resilient biasing polymer biases said second annular protrusion probe tip in a direction away from said wafer.

8. The test head according to claim 1, wherein said at least two protrusion probe tips are formed on said second surface of said wafer by an etch back process.

9. The test head for according to claim 1, wherein said at least two protrusion probe tips are metallized and are located at least one planar height distance from the test head.

10. A system for providing functional wafer level testing, said system comprising:
a test head comprising:
a wafer;
a plurality of protrusions in said wafer, each protrusion of said plurality of protrusions comprising:
an electrical interconnection a first surface of said wafer; and
a probe tip connected with the electrical interconnection protruding from a second surface of said wafer for establishing an electrical connection with a conductive contact of said test wafer,
a substrate supporting said test head and electrically connecting to said test head through said electrical interconnections; and
a tester electrically connected to said test head through said substrate functionally testing at least one circuit on said test wafer when said electrical connection is established by said probe tips of said plurality of protrusions, and the tester communicating with the electrical interconnections.

11. The system according to claim 10, wherein the plurality of protrusion probe tips comprises a pitch range of approximately 1 μm to approximately 100 μm.

12. The system according to claim 10, wherein said wafer further comprises:
an integrated functional tester including internal circuitry, the integrated functional tester electrically communicating with the probe tip.

13. The system according to claim 10, wherein at least one of the plurality of protrusion probe tips comprises:
a portion for puncturing through an oxide layer on said solder bump to establish an electrical connection through said conductive contact with said test wafer.

14. The system according to claim 10, wherein at least one of plurality of protrusion probe tips comprises:
at least two parallel disposed bars to establish an electrical connection through said conductive contact with said test wafer.

15. The system according to claim 10, wherein at least one of the plurality of protrusion probe tips comprises:
an annular protrusion probe tip to establish an electrical connection through conductive contact with said test wafer.

16. The system for providing functional wafer level testing according to claim 10, wherein at least one of the probe tips of at least one of the plurality of protrusions comprises:
a double annular protrusion probe tip to establish an electrical connection through said conductive contact with said test wafer, said double annular protrusion probe tip comprising:
a first annular protrusion probe tip;
a second annular protrusion probe tip disposed within said first annular protrusion probe tip; and
a resilient biasing polymer disposed inside said first annular protrusion probe tip and between said wafer and said second annular protrusion probe tip,
wherein said resilient biasing polymer biases said second annular protrusion probe tip in a direction away from said wafer.

17. The system according to claim 10, wherein the probe tip of the plurality of protrusions are formed on said second surface of said wafer by an etch back process.

18. The system for providing functional wafer level testing according to claim 10, wherein the probe tip of the plurality of protrusions include being metalized.

19. A method of an un-diced test wafer including at least one chip, said method comprising:
providing a test head comprising:
thinning a wafer;
forming a plurality of protrusions in the thinned wafer, each protrusion of said plurality of protrusions comprising:
forming an electrical interconnection on a first surface of said wafer and protruding from the first surface of said wafer; and
forming a corresponding probe tip of the electrical interconnection protruding from a second surface of said wafer for establishing an electrical connection with one of solder connections, pads and electrical contact features of said test wafer; electrically joining said test head to said test wafer through said probe tip of the plurality of protrusions; and
functionally testing said test wafer.

20. The method according to claim 19, further comprising at least one of the following:
one of heating and cooling said test head during said functional testing of said test wafer;
cleaning the probe tip of at least one of said plurality of protrusions;
reworking the probe tip of at least one of said plurality of protrusions;
simultaneously reworking the probe tip of at least one of said plurality of protrusions and said wafer; and
reworking said electrical interconnection of said test head.

21. The method according to claim 19, further comprising forming an insulator over the wafer to provide insulation for conductors including the electrical interconnection and the probe tip of the plurality of protrusions, wherein said electrically joining said test head to said test wafer further comprises:
joining said probe tip of the plurality of probe tips to said one of solder connections, pads and an electrical contact, the electrical contact features being located at one of a single planar height from the wafer during test and a plurality of heights from the wafer during test.

22. The test head according to claim 1, wherein the probe tip of the plurality of protrusions comprises:
a first protrusion probe tip;
a second protrusion probe tip disposed within the first protrusion probe tip; and
a resilient biasing polymer disposed inside the first protrusion probe tip and between the wafer and the second protrusion probe tip.

23. The test head according to claim 1, further comprising a tester integrated within the wafer and functionally testing at least one circuit,
wherein the probe tip of at least one of the plurality of protrusions comprises a plurality of layered portions to establish an electrical connection through the conductive contact.

24. The test head according to claim 1, wherein the dielectric material includes an oxide for insulation, and
wherein the probe tips comprise a layer of a material including a member selected from a group consisting of Cu, Ni, Au, Pd, Co, W and Mo.
